(19) United States
(12) Patent Application Publication
(10) Pub. No.: US 2018/0073124 A1
(43) Pub. Date: Mar. 15, 2018

(54) HARD COATING

(71) Applicant: KABUSHIKI KAISHA KOBE SEIKO SHO (KOBE STEEL, LTD.), Kobe-shi (JP)

(72) Inventors: Hiroaki NII, Kobe-shi (JP); Kenji YAMAMOTO, Kobe-shi (JP)

(73) Assignee: KABUSHIKI KAISHA KOBE SEIKO SHO (KOBE STEEL, LTD.), Kobe-shi (JP)

(21) Appl. No.: 15/554,643

(22) PCT Filed: Feb. 24, 2016
(86) PCT No.: PCT/JP2016/055531

§ 371 Date: Aug. 30, 2017

(30) Foreign Application Priority Data
Apr. 13, 2015 (JP) 2015-081410

(51) Int. Cl. C23C 14/06; C23C 16/34; C23C 14/32; C23C 14/00; C09D 1/00; B23B 27/14

(52) U.S. Cl. CPC C23C 14/0641; C23C 16/347; C23C 14/325; B23B 2228/10; C23C 14/0084; C09D 1/00; B23B 27/14; C23C 14/0664

(57) ABSTRACT

A hard coating to be disposed on or over a substrate surface is provided. The hard coating includes a nitride or carbonitride containing Al, Cr, and at least one element X. The element X has an atomic number higher than Cr and is a Group 4 element; a Group 5 element, or a Group 6 element. The hard coating has maximum X element concentration points repeatedly present in a vertical direction to the substrate surface and one or more minimum X element concentration points present between adjacent two maximum X element concentration points in the vertical direction. The hard coating has a chemical composition continuously varying in the vertical direction.

### TECHNICAL FIELD

The present invention relates to hard coatings. In particular, the present invention relates to a hard coating having excellent wear resistance.

### BACKGROUND ART

For longer lives of tools (jigs and tools) such as cutting tools and forming tools, hard coatings made typically of AlCrN have been applied onto the tools to allow the tools to have better wear resistance.

For example, Patent literature (PTL) 1 discloses a hard coating having a structure as follows in terms of distribution of element concentrations. In the structure, maximum Al concentration points having a compositional formula: (Cr_{1-X}Al_{X})N, and minimum Al concentration points having a compositional formula: (Cr_{1-Y}Al_{Y})N are alternately repeatedly present, and the Al content continuously varies. The literature also mentions that this configuration allows the resulting coated superhard tool (cemented carbide tool) to have better resistance to chipping.

PTL 2, PTL 3, and PTL 4 each describe that a hard coating, when allowed to have an alternate multilayer structure including a thin layer (A) and a thin layer (B), each of which is a composite nitride of Cr, Al, and a specific element such as Ta, allows the resulting surface-coated cutting tool to have better wear resistance.

### CITATION LIST

### Patent Literature

PTL 1: Japanese Patent No. 3969230

PTL 2: Japanese Unexamined Patent Application Publication (JP-A) No. 2007-105843

PTL 3: JP-A No. 2009-101475

PTL 4: Japanese Patent No. 5459618

### SUMMARY OF INVENTION

### Technical Problem

However, hard coatings each including multiple layers differing in chemical composition concentration or in microstructure as in PTL 2, PTL 3, and PTL 4 are susceptible to delamination or separation at the interface between layers and may have lower wear resistance.

Even hard coatings devoid of multilayer structures, as disclosed in PTL 1, require further investigations, because tools such as cutting tools need still better wear resistance.

The present invention has been made in consideration of these circumstances and has an object to actually provide a hard coating having excellent wear resistance, where the hard coating, when disposed on or over a tool such as a cutting tool or a forming tool, allows the tool (such as the cutting tool) to have sufficiently better wear resistance.

### Solution to Problem

The present invention provides a hard coating to be disposed on or over a substrate surface. The hard coating includes a nitride or a carbonitride, each of which contains Al, Cr, and at least one element X. The element X has a higher atomic number as compared with Cr and is selected from the group consisting of Group 4 elements, Group 5 element, and Group 6 elements. In the hard coating, two or more maximum X concentration points and one or more minimum X concentration points are present. The maximum X concentration points are points at which the concentration of the element X reaches maximal. The maximum X concentration points are present repeatedly in a vertical direction to the substrate surface. The minimum X concentration points are points at which the concentration of the element X reaches minimal. The minimum X concentration points are present between two of the maximum X concentration points adjacent to each other in the vertical direction. The hard coating has a chemical composition continuously varying in the vertical direction. The maximum X concentration points are points having the compositional formula: AlₘCr₍₁₋ₘ₋ₙ₎Xₙ(N_{α}C_{(1-α)}), where the atomic ratios m, n and α meet conditions as follows: 0.25≦m≦0.70; 0.05≦n≦0.45; 1−m−n>0; and 0.50≦α≦1. The minimum X concentration points are points having the compositional formula: AlₓCr_{(1-x-y)}X_{y}(N_{β}C_{(1-β)}), where the atomic ratios x, y and β meet conditions as follow: 0.40≦x≦0.80; 0.001≦y≦0.35; 0.50≦β1; 1−x−y>0; and n/y>1.0.

In a preferred embodiment of the present invention, the hard coating has a total thickness of 0.1 to 20 μm.

In a preferred embodiment of the present invention, the hard acting includes a fibrous microstructure. The fibrous microstructure includes crystals having an average aspect ratio of 2.5 or more and having an angle of 60° to 120°, where the angle is formed by major axes of the crystals with a layer defined by a series of the maximum X concentration points.

In a preferred embodiment of the present invention, the crystals have an average length of minor axes of 0.1 to 30 nm.

The present invention also includes a hard-coated member including a substrate, and the hard coating disposed on or over the substrate.

### Advantageous Effects of Invention

The present invention can actually provide a hard coating having excellent wear resistance. Assume that this hard coating is disposed (formed) on tools such as cutting tools and forming tools, in particular, on tools for heavy cutting such as drilling or gear cutting. The hard coating in this case allows the tools such as cutting tools to have better wear resistance and to have longer lives.

### BRIEF DESCRIPTION OF DRAWINGS

FIG. 1 illustrates a schematic cross-sectional view of a hard coating according to the present invention;

FIG. 2A is a diagram schematically illustrating how the chemical composition of the hard coating according to the present invention varies in the thickness direction, in an embodiment where maximum X concentration points and a minimum X concentration point are present alternately;

FIG. 2B is a diagram schematically illustrating how the chemical composition of a hard coating according to the present invention varies in the thickness direction, in an embodiment where a wave of the X concentration not corresponding to the maximum X concentration point and the minimum X concentration point is present;

FIG. 2C is a diagram schematically illustrating how the chemical composition of a hard coating according to the present invention varies in the thickness direction, in an embodiment where two or more minimum X concentration points are present between adjacent maximum X concentration points;

FIG. 3A depicts a transmission electron microscope (TEM) image of the cross section of a coating of Test No. 5;

FIG. 3B depicts a transmission electron microscope (TEM) image of the cross section of a coating of Test No. 20;

FIG. 4A depicts a transmission electron microscope (TEM) image of the cross section of a coating Test No. 19;

FIG. 4B depicts a transmission electron microscope (TEM) image of the cross section of a coating of Test No. 18;

FIG. 5 is a schematic cross sectional view of a hard coating according to the present invention;

FIG. 6 is a diagram schematically illustrating how the chemical composition of the hard coating according to the present invention varies in the thickness direction;

FIG. 7 is a schematic view of a fibrous microstructure of a hard coating according to the present invention; and

FIG. 8 is a schematic view of a fibrous microstructure of another hard coating according to the present invention.

### DESCRIPTION OF EMBODIMENTS

To achieve the object, the inventors of the present invention made intensive investigations on hard coatings to be formed on tools such as cutting tools and forming tools. As a result, the inventors have found that a hard coating having excellent wear resistance can be obtained by incorporating, into a nitride or carbonitride each containing Al and Cr, at least one element X having a higher atomic number as compared with Cr and being selected from the group consisting of Group 4 elements, Group 5 elements, and Group 6 elements; by allowing maximum X concentration points and one or more minimum X concentration points as mentioned below to be present repeatedly in a vertical direction to a substrate surface; and controlling the chemical composition of the hard coating to continuously vary in the vertical direction. The maximum X concentration points are points each having the compositional formula: AlₘCr₍₁₋ₘ₋ₙ₎Xₙ(N_{α}C_{(1-α)}), where the atomic ratios m, n, and α meet the conditions: 0.25≦m≦0.70, 0.05≦n≦0.45, 1−m−n>0, and 0.50≦α≦1. The minimum X concentration points are points each having the compositional formula: AlₓCr_{(1-x-y)}X_{y}(N_{β}C_{(1-β)}), where the atomic ratios x, y, and β meet the conditions: 0.40≦x≦0.80, 0.01≦y≦0.35, 0.50≦β≦1, 1−x−y>0, and n/y>1.0. The present invention has been made on the basis of these findings.

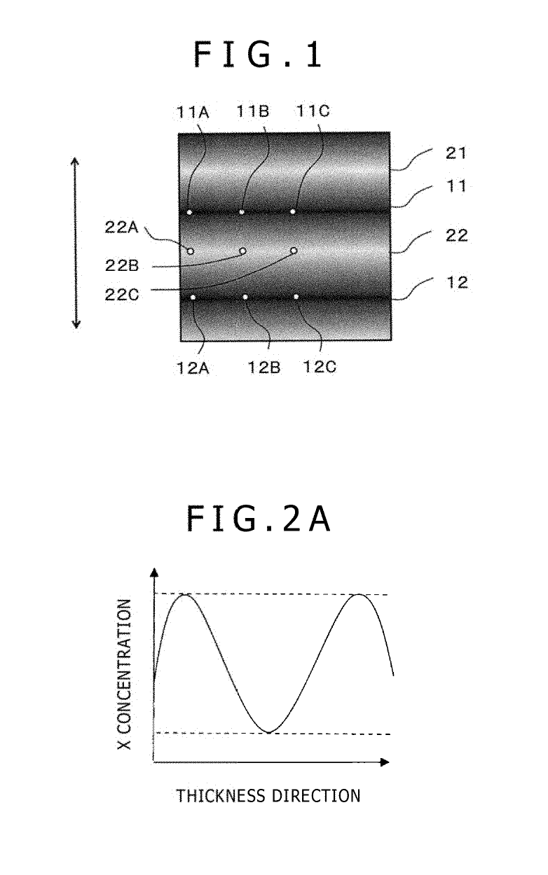

The maximum X concentration points and minimum X concentration points of the hard coating, which feature the present invention, will be described below with reference to FIG. 1. As schematically illustrated in FIG. 1, a hard coating according to an embodiment of the present invention has maximum X concentration points 11A, 11B, 11C, 12A, 12B, and 12C, at which the concentration of the element X reaches maximal. In FIG. 1, series of the maximum X concentration points define maximum X concentration layers 11 and 12. In addition, the hard coating according to the present invention has minimum X concentration points 21A, 21B, 21C, 22A, 22B, and 22C, at which the concentration of the element X reaches minimal. In FIG. 1, a series of the minimum X concentration points 21A, 21B, and 21C defines a minimum X concentration layer 21, and another series of the minimum X concentration points 22A, 22B, and 22C defines a minimum X concentration layer 22. The maximum X concentration points and the minimum X concentration points are alternately present repeatedly in a vertical direction to the substrate surface, namely, in the double-pointed arrow direction in FIG. 1. Hereinafter the vertical direction to the substrate surface is also referred to as a “thickness direction”.

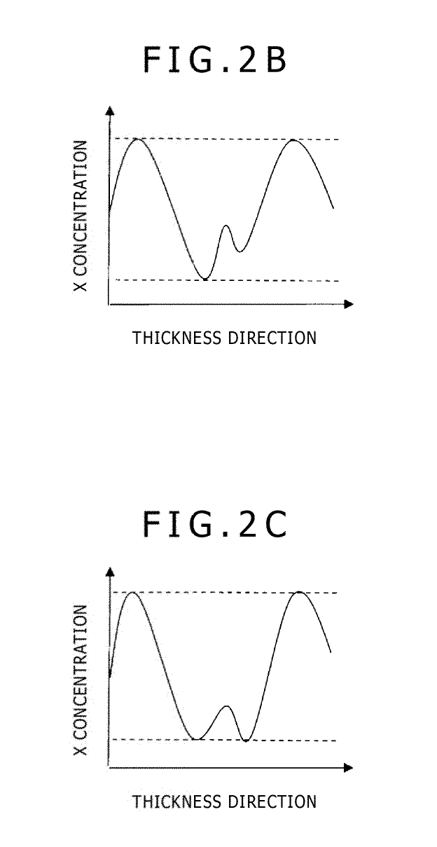

In FIG. 1, the maximum X concentration points and the minimum X concentration points are alternately present. However, the hard coating according to the present invention does not always have to include maximum X concentration points and minimum X concentration points being alternately present in the thickness direction. The hard coating may further have one or more waves of the X concentration, which waves do not correspond to the maximum X concentration points and the minimum X concentration points, as illustrated in FIG. 2B described below. In the hard coating, two or more minimum X concentration points may be present between two maximum X concentration points adjacent to each other in the thickness direction, as illustrated in FIG. 2C described below.

The maximum X concentration points preferably range in a direction parallel to the substrate surface to form (to define) a layer as illustrated in FIG. 1. However, the maximum X concentration points do not always have to range sequentially and may include a non-sequential portion. In the present invention, a state in which the maximum X concentration points sequentially range, and a state in which the maximum X concentration points range non-sequentially with a non-sequential portion, as described above, are collectively referred to as a “maximum X concentration layer”.

The minimum X concentration points also preferably range sequentially in a direction parallel to the substrate surface to form (to define) a layer, as illustrated in FIG. 1. However, the minimum X concentration points do not always have to range sequentially, but may include a non-sequential portion. In the present invention, a state in which the minimum X concentration points sequentially range, and a state in which the minimum X concentration points range non-sequentially with a non-sequential portion, as described above, are collectively referred to as a “minimum X concentration layer”.

The element X contained at the maximum X concentration points and the maximum X concentration points is at least one element having a higher atomic number as compared with Cr and being selected from the group consisting of Group 4 elements, Group 5 elements, and Group 6 elements. The element X contributes to higher hardness of the hard coating and forms a stable oxide. The maximum X concentration points therefore contribute to higher hardness of the hard coating and to the formation of stable oxides and allow the hard coating to have better wear resistance. In contrast, the minimum X concentration points have relatively higher Al concentrations, thereby contribute to better oxygen-barrier properties as described below, and allow the hard coating to have better wear resistance.

The maximum X concentration points can be identified using a TEM, as described in experimental examples below. The element X is an element having a higher atomic weight as compared with Al and Cr. A portion enriched with the element X therefore resists transmission of electron beams and looks black in a TEM image. Thus, a point with a lowest lightness in the TEM image is defined as a maximum X concentration point. In addition, to identity the maximum X concentration point strictly, an energy-dispersive X-ray (EDX) analysis may be performed to identify a point with a highest X concentration as the maximum X concentration point. In contrast, a point with a highest lightness in the TEM image is defined as a minimum X concentration point. In addition, to identify the minimum X concentration point strictly, an EDX analysis may be performed to identify a point with a lowest X concentration as the minimum X concentration point.

The hard coating according to the present invention has a chemical composition continuously varying in the thickness direction, thereby avoid the formation of interfaces, and actually has better wear resistance. The term “continuously” refers to that, for example as illustrated in FIG. 1, the chemical composition varies not stepwise, but smoothly from the maximum X concentration points 11A, 11B, and 11C respectively to the minimum X concentration points 22A, 22B, and 22C; and varies not stepwise, but smoothly from the minimum X concentration points 22A, 22B, and 22C respectively to the maximum X concentration points 12A, 12B, and 12C. FIGS. 2A, 2B, and 2C are schematic diagrams illustrating how the chemical composition of the hard coating according to the present invention varies in the thickness direction. With reference to FIGS. 2A and 2B, the continuous variation in chemical composition can be easily understood. Assume that two or more minimum X concentration points are present between two maximum X concentration points adjacent to each other in the thickness direction. In this case, the term “continuously” refers to that, as illustrated in FIG. 2C, the chemical composition varies not stepwise, but smoothly in the thickness direction between a maximum X concentration point and a minimum X concentration point, and between the adjacent minimum X concentration points.

The chemical compositions and other conditions of the maximum X concentration points and the minimum X concentration points will be illustrated in detail below.

Maximum X Concentration Point

The element X is an element that contributes to higher hardness of the hard coating and to the formation of a stable oxide, as described above. In addition, the element X also contributes to the formation of a fibrous microstructure as described later. To effectively offer such advantageous effects, the atomic ratio of the element X at the maximum X concentration points is, in terms of lower limit, controlled to 0.05 or more. The atomic ratio n of the element X at the maximum X concentration points is hereinafter also referred to as an “X content n”. The X content n is, in terms of lower limit, preferably 0.10 or more, more preferably 0.14 or more, furthermore preferably 0.18 or more, and still more preferably 0.240 or more. In contrast, a stable oxide tends to more readily form with an increasing X content n. However, the element X, if present in an excessively high content, may form a compound mainly including the element X, and this may cause the hard coating to be brittle and to have lower wear resistance. To eliminate or minimize this, the X content n is, in terms of upper limit, controlled to be 0.45 or less. The X content n is, in terms of upper limit, preferably 0.43 or less, and more preferably 0.40 or less.

When two or more different elements X are present, the term “X content n” refers to the total of atomic ratios of these elements X. When one type of element X is present, the term “X content n” refers to the atomic ratio of this element X.

Aluminum (Al), when oxidized, forms a dense oxide coating and contributes to better oxygen-barrier properties. In addition, Al effectively contributes to better wear resistance and higher hardness. To effectively offer such advantageous effects, the atomic ratio of Al at the maximum X concentration points is, in terms of lower limit, controlled to 0.25 or more. The atomic ratio m of Al at the maxim um X concentration points is hereinafter also referred to as an “Al content m”. The Al content m is, in terms of lower limit, preferably 0.28 or more, and more preferably 0.30 or more. In contrast, Al, if present in an excessively high content, may form hexagonal crystals having low hardness and may cause the hard coating to have lower hardness. To eliminate or minimize this, the Al content m is, in terms of upper limit, controlled to 0.70 or less. The Al content m is, in terms of upper limit preferably 0.69 or less, and more preferably 0.68 or less.

Chromium (Cr) effectively contributes to higher strength of the coating. The atomic ratio 1−m−n of Cr at the maximum X concentration points is a value resulting from subtracting the atomic ratio of the element X and the atomic ratio of Al from 1. The atomic ratio 1−m−n of Cr at the maximum X concentration points is hereinafter also referred to as a “Cr content 1−m−n”. The Cr content 1−m−n is, in terms of lower limit, greater than 0. The Cr content 1−m−n may be, in terms of lower limit, topically 0.10 or more, more typically 0.12 or more, and furthermore typically 0.15 or more. In contrast, the upper limit of the Cr content 1−m−n is calculated from the chemical composition to be 0.70 or less. The Cr content 1−m−n may be, in terms of upper limit, typically 0.50 or less, more typically 0.45 or less, and furthermore typically 0.40 or less.

The atomic ratio 1−αof carbon (C) at the maximum X cancellation points is a value resulting from subtracting the atomic ratio α of nitrogen (N) from 1 and is from 0 to 0.50 according to the calculation. The atomic ratio 1−α of carbon in the maximum X concentration points is hereinafter also referred to as a “carbon content 1−α”. Likewise, the atomic ration α of nitrogen at the maximum X concentration points is hereinafter also referred to as “nitrogen content α”.

The maximum X concentration point represented by AlₘCr₍₁₋ₘ₋ₙ₎X_{α}(N_{α}C_{(1-α)}) in the present invention includes (is made of) a nitride when the carbon content is zero. Thus, the hard coating according to the present invention is fundamentally based on a nitride. However, the hard coating may further contain carbon for better lubricity of the coating.

To effectively offer the advantageous effects of carbon, the carbon content 1−α is, in terms of lower limit, preferably 0.05 or more, and more preferably 0.10 or more. In contrast, carbon, if present in an excessively high content may cause the hard coating to lose toughness and to become brittle. To eliminate or minimize this, the carton content 1−α is controlled, in terms of upper limit, to be 0.50 or less. The carbon content 1−α is, in terms of upper limit, preferably 0.45 or less, and more preferably 0.40 or less.

Next, the minimum X concentration points will be described.

Minimum X Concentration Points

The element X contributes to higher hardness of the hard coating and to the formation of a stale oxide, as described above. In addition, the element X contributes to the formation of the fibrous microstructure. To effectively offer such advantageous effects, the atomic ratio of the element X at the minimum X concentration points is, in terms of lower limit, controlled to be 0.01 or more. The atomic ratio y of the element X at the minimum X concentration points is hereinafter also referred to as an “X content y”. The X content y is, in terms of lower limit, preferably 0.05 or more, more preferably 0.06 or more, and furthermore preferably 0.065 or more. In contrast, a stable oxide tends to form more easily with an increasing X content y. However, the element X, if present in an excessively high content, may form a compound mainly including the element X and may cause the hard coating to be brittle and to have lower wear resistance. To eliminate or minimize this, the X content y is, in terms of upper limit, controlled to be 0.35 or less. The X content y is, in terms of upper limit, preferably 0.33 or less, more preferably 0.30 or less, and furthermore preferably less than 0.280.

When two or more different elements X are present, the term “X content y” refers to the total of atomic ratios of these elements. When one type of element X is present, the term “X content y” refers to the atomic ratio of this element.

When the element X concentration at the maximum X concentration points is larger than the element X concentration at the minimum X concentration points, the maximum X concentration points and the minimum X concentration points can effectively offer the advantageous effects of them respectively. Specifically, the ratio of the X content n to the X content y should be greater than 1.0. The ratio is preferably 1.1 or more, more preferably 1.2 or more, furthermore preferably 1.25 or more, and still more preferably 1.3 or more. The ratio is not limited in terms of upper limit. However, if the ratio is excessively high, a compound mainly including a component of the element X may be formed, and this may cause the hard coating to become brittle and to have lower wear resistance. To eliminate or minimize this, the ratio is, in terms of upper limit, preferably 5.0 or less, and more preferably 4.5 or less.

Al forms a dense (compact) oxide coating when oxidized, and contributes to better oxygen-barrier properties. In addition, Al is also effective for better wear resistance and higher hardness. To effectively offer such advantages effects, the atomic ratio of Al at the minimum X concentration points is controlled, in terms of lower limit, to be 0.40 or more. The atomic ratio x of Al at the minimum X concentration points is hereinafter also referred to as an “Al content x”. The Al content x is, in terms of lower limit, preferably 0.45 or more, and more preferably 0.49 or more. In contract, Al, if present in an excessively high content, may form hexagonal crystals having low hardness and may cause the hard coating to have lower hardness. To eliminate or minimize this, the Al content x is controlled, in terms of upper limit, to be 0.80 or less. The Al content x is, in terms of upper limit, preferably 0.78 or less, and more preferably 0.75 or less.

Cr effectively contributes to higher strength of the coating. The atomic ratio 1−x−y of Cr at the minimum X concentration points is a value resulting from subtracting the atomic ratio of the element X and the atomic ratio of Al from 1. The atomic ratio of 1−x−y of Cr at the minimum X concentration points hereinafter also referred to as a “Cr content 1−x−y”. The Cr content 1−x−y is, in terms of lower limit, greater than 0. The Cr content 1−x−y may be, in terms of lower limit, typically 0.05 or more, more typically 0.10 or more, and furthermore typically 0.14 or more. In contrast, the upper limit of the Cr content 1−x−y can be calculated from the chemical composition as 0.59 or less. The Cr content 1−x−y may be, in terms of upper limit, typically 0.50 or less, more typically 0.45 or less, and furthermore typically 0.40 or less.

The atomic ratio 1−⊕ of carbon at the minimum X concentration points is a value resulting from subtracting the atomic ratio β of nitrogen from 1 and is from 0 to 0.50 according to the calculation. The atomic ratio 1−β of carbon at the minimum X concentration points is hereinafter also referred to as a “carbon content 1−β”. Likewise, the atomic ratio β of nitrogen at the minimum X concentration points is hereinafter also referred to as a “nitrogen content β”.

The ranges of the nitrogen content β and the carbon content 1−β, the reasons for setting the ranges, and preferred upper and lower limits of the contents at the minimum X concentration points are as with the ranges of the nitrogen content α and the carbon content 1−α, the reasons for setting the ranges, and preferred upper and lower limits of the contents at the maximum X concentration points.

The average distance in the thickness direction between a maximum X concentration layer and a minimum X concentration layer is not limited, where the average distance is measured by the method described in the experimental examples. However, the average distance is preferably 5 nm or more, and more preferably 10 nm or more, from the viewpoint of imparting functions to layers differing in concentrations. The average distance is, in terms of upper limit, preferably 120 nm or less, and more preferably 100 nm or less, from the viewpoint of relaxing stress in the layers.

The average distance in the thickness direction between adjacent maximum X concentration layers in not limited, but is preferably 15 nm or more, and more preferably 20 nm or more, from the viewpoint of film-forming speed. In contrast, the average distance, in terms of upper limit is preferably 200 nm or less, and more preferably 150 nm or less, from the viewpoint of eliminating or minimizing fracture in the layers.

The hard coating according to the present invention may have any total thickness not limited. However, the hard coating, if having an excessively small total thickness, may hardly offer excellent wear resistance sufficiently. To eliminate or minimize this, the hard coating may have a total thickness of preferably 0.1 μm or more, and more preferably 0.5 μm or more. In contrast, the hard coating, if having an excessively large total thickness, tends to be chipped or separated during cutting. To eliminate or minimize this, the hard coating may have a total thickness of preferably 20 μm or less, and more preferably 1.5 μm or less.

The hard coating according to the present invention may include a fibrous microstructure as follows. This fibrous microstructure includes crystals having an average aspect ratio of 2.5 or more and having an angle of 60° to 120°, where the angle is formed by major axes of the crystals with a layer defined by a series of the maximum X concentration points. The hard coating, when including the fibrous microstructure, can have still better wear resistance.

The crystals constituting the fibrous microstructure more resist fracture and allow the hard coating to have still better wear resistance with the angles formed by the major axes of the crystals with the layer defined by a series of the maximum X concentration points approaching 90°. Accordingly, the angle formed by major axes of the crystals with the layer defined by a series of the maximum X concentration points is preferably 60° to 120° as described above, and more preferably 70° to 110°.

The average aspect ratio of the crystals is, in terms of lower limit, preferably 2.5 or more, and more preferably 3 or more, where the avenge aspect ratio refers to the ratio of the average length of major axes to the average length of minor axes. In contrast, the average aspect ratio may be, in terms of upper limit about 50 in consideration typically of the chemical composition and production conditions of the hard coating according to the present invention.

The crystals may have an average length of minor axes of preferably 0.1 nm or more, and more preferably 2.5 nm or more, thorn the viewpoint of higher strength. In contrast, the crystals, if having excessively large minor axes, may be transformed from the fibrous microstructure into a granular microstructure. To eliminate or minimize this, the crystals may have an average length of minor axes of preferably 30 nm or less, and more preferably 25 nm or less.

The fibrous microstructure is preferably present approximately overall the coating.

The hard coating as described above, when disposed on or over a substrate, can actually provide a hard-coated member having excellent wear resistance, which member is exemplified typically by tools such as cutting tools and forming tools, in particular, tools for heavy cutting such as drilling and gear cutting.

The substrate is not limited in type and is exemplified by, but not limited to, substrates including WC-based hard metals such as WC—Co alloys, WC—TiC—Co alloys, WC—TiC (TaC or NbC)-Co alloys, and WC-(TaC or NbC)-Co alloys; cermets such as TiC—NiMo alloys and TiC—TiN—Ni—Mo alloys; high-speed steels such as SKH 51 and SKD 61 prescribed in JIS G 4403:2006; ceramics; cubic-crystal boron nitride sintered compacts; diamond sintered compacts; silicon nitride sintered compacts; and mixtures of aluminum oxide and titanium carbide.

Before the formation of the hard coating according to the present invention on or over the substrate, an intermediate layer may be disposed (formed) between the substrate and the hard coating so as to offer better adhesion between them. The intermediate layer may be formed typically from another metal, nitride, carbonitride, or carbide.

The hard coating according to the present invention may be formed on or over the substrate using a known technique or process such as physical vapor deposition processes (PVD processes; physical vapor phase epitaxy) and chemical vapor deposition processes (CVD processes; chemical vapor phase epitaxy). Effective examples of these processes include ion plating processes such as arc ion plating (AIP) process; and reactive PVD processes such as sputtering process.

Assume that the hard coating is deposited by AIP process. In this case, the chemical composition is continuously varied between the maximum X concentration points and the minimum X concentration point(s) typically, but non-limitingly, by a method of arranging targets having different X element concentrations to face each other and performing discharging; or by a method of discharging using a single target while periodically changing the arc current; or by a method of periodically changing the gas pressure; or by a method of periodically changing the distance between the target and the substrate. However, the method in the present invention for forming the hard coating is not limited to these methods. The chemical composition can be continuously varied between the maximum X concentration points and the minimum X concentration point(s) by the method of periodically changing the distance between the target and the substrate, because the probability of reaching the substrate at a specific distance varies with the atomic weight.

The continuous variation in chemical composition between the maximum X concentration points and the minimum X concentration point(s) as described above promotes crystal growth in a specific direction in the hard coating. The film-forming (deposition) method of continuously varying the chemical composition between the maximum X concentration points and the minimum X concentration point(s) is therefore effective in forming the fibrous microstructure specified in the present invention.

In addition, uniform film-formation (deposition) on or over the substrate is effective in allowing the angle to approach 90°, where the angle is formed by the major axes of crystals constituting the fibrous microstructure specified in the present invention with the layer defined by a series of the maximum X concentration posits.

A non-limiting example of the target, which serves as an evaporation source, is a target including Al, Cr, and the element X, which elements are chemical components, excluding carbon and nitrogen, to constitute the coating.

The deposition may be performed typically using nitrogen gas as an atmospheric gas. To form a carbon-containing hard coating, a hydrocarbon gas may be further used in combination. Non-limiting examples of the hydrocarbon gas include methane and acetylene. The atmospheric gas may further include Ar.

Non-limiting example of the apparatus to form or deposit the hard coating include an AIP apparatus; and a PVD composite apparatus including both an arc evaporation source and a spoiling evaporation source. Simultaneous discharging of these evaporation sources enables deposition of elements that resist evaporation by sputtering, while surely performing deposition at high speed by the AIP process.

When the AIP apparatus is used, deposition may be performed typically under conditions as follows.

The substrate temperature in the deposition may be selected as appropriate according to the type of the substrate. The substrate temperature in the deposition is preferably 300° C. or higher, and more preferably 400° C. or higher, from the viewpoint of surely providing adhesion between the substrate and the hard coating. The substrate temperature is preferably 800° C. or lower, and more preferably 700° C. or lower, from the viewpoint typically of eliminating or minimizing deformation of the substrate.

In addition to the above-mentioned conditions, the deposition may be performed under conditions of an atmospheric gas total pressure of 0.5 Pa to 10 Pa, an arc current of 10 to 250 A, and a direct-current bias voltage to be applied to the substrate of −10 to −200V.

### EXAMPLES

The present invention will be illustrated in further detail with reference to several experimental examples below. It should be noted, however, that the examples are by no means intended to limit the scope of the present invention; that various changes and modifications can naturally be made therein without deviating from the sprit and scope of the present invention as described herein: and that all such changes and modifications should be considered to be within the scope of the present invention.

Hard coatings were deposited on substrates using an AIP apparatus. Specifically, the hard coatings were each deposited in the following manner. As substrates, there were prepared a cutting tool (MultiDrill MDS 085 SG, supplied by Sumitomo Electric Industries, Ltd., having a diameter of 8.50 mm, and including Al as a base metal (as non-coated)) for cutting test; and a mirror-finished superhard test specimen (13 mm long by 5 mm thick) for cross-section evaluation. The cutting tool and the superhard test specimen were ultrasonically cleaned in ethanol and were each mounted on the rotary table of the AIP apparatus in a position at a predetermined distance from the central axis. After evacuating the apparatus to 5×10⁻³ Pa, the substrates were heated up to 500° C. and etched with Ar ions for 5 minutes. Next, nitrogen gas was introduced to a pressure of 4 Pa, and each of targets having the chemical compositions of Nos. 1 to 17, 19, 21 to 23, 25, and 26 given in Table 1 and having a diameter of 100 mm was placed on a cathode (evaporation source). Next, while the substrates were rotated on the rotary table at a rate of 14 rpm, the rotary table was revolved at a rate of 5 rpm. A direct-current bias voltage of −70 V was applied to the substrates, and a current of 150 A was fed between the cathode and the anode to generate arc discharge. The deposition was performed while the deposition time was adjusted so as to finally deposit a coating having a total thickness of about 3 μm, and yielded a cross-section evaluation sample and a cutting test sample.

TABLE 1

Target chemical composition (atomic ratio)

| Number | Al | Cr | Type of X | X content |
|---|---|---|---|---|
| 1 | 0.65 | 0.25 | Zr | 0.10 |
| 2 | 0.65 | 0.25 | Nb | 0.10 |
| 3 | 0.65 | 0.25 | Mo | 0.10 |
| 4 | 0.65 | 0.25 | Hf | 0.10 |
| 5 | 0.65 | 0.25 | Ta | 0.10 |
| 6 | 0.65 | 0.25 | W | 0.10 |
| 7 | 0.70 | 0.20 | Mo | 0.10 |
| 8 | 0.70 | 0.20 | Ta | 0.10 |
| 9 | 0.60 | 0.15 | Mo | 0.25 |
| 10 | 0.60 | 0.15 | Ta | 0.25 |
| 11 | 0.60 | 0.35 | Mo | 0.05 |
| 12 | 0.60 | 0.35 | Ta | 0.05 |
| 13 | 0.65 | 0.25 | Mo, W | 0.05, 0.05 |
| 14 | 0.65 | 0.25 | Nb, Ta | 0.05, 0.05 |
| 15 | 0.65 | 0.25 | Zr, Hf | 0.05, 0.05 |
| 16 | 0.65 | 0.25 | Zr | 0.10 |
| 17 | 0.65 | 0.25 | Zr | 0.10 |
| 18 | 0.65 | 0.35 | — | 0 |
| 19 | 0.65 | 0.35 | — | 0 |
| 20 | 0.65 | 0.25 | Zr | 0.10 |
| 21 | 0.40 | 0.60 | Mo | 0.10 |
| 22 | 0.65 | 0.25 | V | 0.10 |
| 23 | 0.65 | 0.25 | Zr | 0.10 |
| 24 | — | — | — | — |
| 25 | 0.58 | 0.15 | Mo | 0.27 |
| 26 | 0.55 | 0.15 | Mo | 0.30 |

The coatings according to Test Nos. 16, 17, and 23 were allowed to include carbon by using a nitrogen gas mixture containing 20 volume percent of methane gas.

Test Nos. 18 and 20 employed targets having the chemical compositions respectively of Nos. 18 and 20 in Table 1 and having a diameter of 100 mm, but underwent deposition in which the substrate on the rotary table was neither rotated nor revolved, but left stand in front of the target during the deposition. The other conditions are as with Test Nos. 1 to 15, 21, 22, 25, and 26. In Test No. 24, no coating was deposited on the substrate.

Cross-Sectional Observation

The total thickness of each sample coating was determined in the following manner. The superhard test specimen bearing the coating, namely, the cross-section evaluation sample was processed using the following “sample preparation apparatus”, and the thickness of which was measured using the following “observation apparatus”. The coatings according to Test Nos. 1 to 23, 25, and 26 were found to have a total thickness of about 3 μm.

Sample Processing
Simple preparation apparatus: Focused Ion Beam System FB 2000A, supplied by Hitachi, Ltd.
Observation apparatus: High-performance Ion Microscope SMI 9200, supplied by SII NanoTechnology Inc.
Acceleration voltage: 30 kV (FIB regular processing)
Ion source: Ga
Preparation method: The superhard test specimen was processed by focused ion beam (FIB) process. The test specimen was coated with a carbon layer using a high-vacuum vapor deposition apparatus and the FIB system to protect the outermost surface of the test specimen, and then a test piece was sampled therefrom by FIB microsampling. The sampled test piece was thinned by FIB processing to such a thickness that can be observed with a transmission electron microscope (TEM).

Chemical Composition Analysis
Apparatus used in observation: Field Emission Transmission Electron Microscope JEM-2010 FEDX, supplied by JEOL Ltd.
Analyzer: Energy Dispersive X-ray Spectrometry (EDX) Analyzer Vantage, supplied by Noran (attached to JEM-2010F)
Acceleration voltage 200 kV
Observation magnification: 750000 times

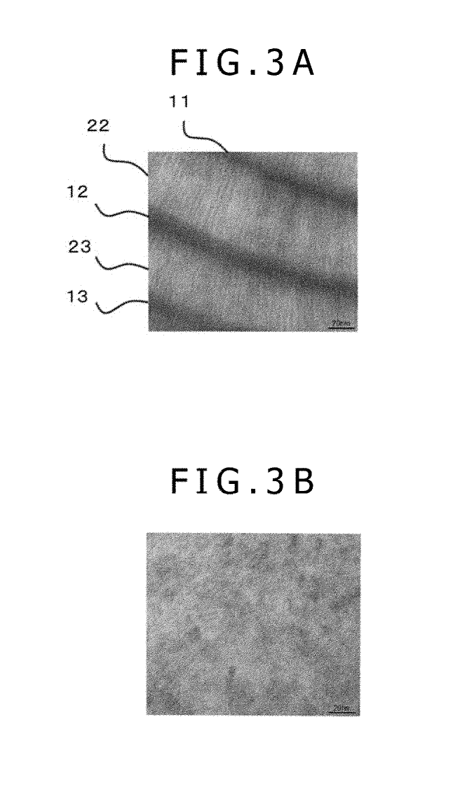

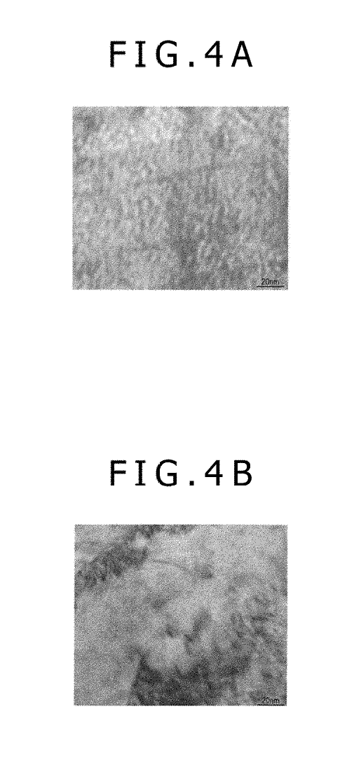

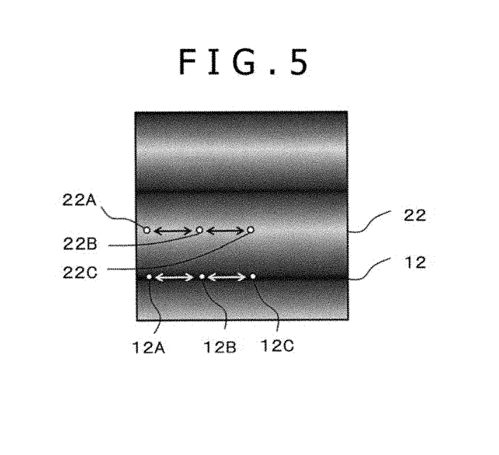

The depth of one-fifth of the total thickness from the coating outermost surface was defined as an observation depth in the coating cross-section of the cross-section evaluation sample after the FIB processing. At the observation depth, a TEM photomicrograph as a bright field image was taken in arbitrary one view field. The photograph of a sample having an unclear microstructure was taken as an underfocus image. FIGS. 3A, 3B, 4A, and 4B depict TEM images respectively of Test Nos. 5, 20, 19, and 18. The TEM image in FIG. 3A is a bright field image, and the TEM images in FIGS 3B, 4A, and 4B are underfocus images. As shown in FIG. 3A, a portion with lowest lightness was defined as a maximum X concentration layer 12, which is defined by a series of maximum X concentration points. Portions having highest lightness and present between the maximum X concentration layer 12 and other maximum X concentration layers 11 and 13 were defined as minimum X concentration layers 22 and 23, each of which is defined by a series of minimum X concentration points. As illustrated in FIG. 5, three maximum X concentration points 12A, 12B, and 12C in one maximum X concentration layer 12 were defined at intervals of 20 nm or more in the direction of the double-pointed arrow, which is a direction parallel to the substrate surface. Chemical compositions of the maximum X concentration points 12A, 12B, and 12C were measured using the EDX attached to the TEM and the average of the measurements was defined as the chemical composition of the maximum X concentration points. Likewise, as illustrated in FIG. 5, three minimum X concentration points 22A, 22B, and 22C in one minimum X concentration layer 22 were defined at intervals of 20 nm or more in the direction of the double-pointed arrow, which is a direction parallel to the substrate surface; chemical compositions of the three points were measured, and the average of the measurements was defined as the chemical composition of the minimum X concentration points. In the EDX analysis, when Al, Cr, and the element X alone were measured, the total atomic ratio was defined as 1; and when nitrogen and carbon alone were measured, the total atomic ratio was defined as 1. Test No. 20 had approximately no difference lightness in the coating, as shown in FIG. 3B; and Test No. 18 had a difference in lightness, but included no layer in the coating, as shown in FIG. 4B. For these test samples, chemical compositions were analyzed in a similar manner at positions approximately corresponding to the maximum concentration layers 11, 12, and 13 and the minimum X concentration layers 22 and 23 in FIG. 3A. Results of these are presented in Table 2.

TABLE 2

| | Chemical composition of maximum X | | | | | | Chemical composition of minimum X | | | | | | Ratio of X |
|---|---|---|---|---|---|---|---|---|---|---|---|---|---|
| | concentration point (atomic ratio) | | | | | | concentration point (atomic ratio) | | | | | | content n |
| Test | | | Type | X content | | | | | Type | X content | | | to X |
| number | Al | Cr | of X | (X content n) | N | C | Al | Cr | of X | (X content y) | N | C | content y |
| 1 | 0.425 | 0.284 | Zr | 0.291 | 1 | 0 | 0.648 | 0.243 | Zr | 0.109 | 1 | 0 | 2.7 |
| 2 | 0.433 | 0.274 | Nb | 0.293 | 1 | 0 | 0.564 | 0.304 | Nb | 0.132 | 1 | 0 | 2.2 |
| 3 | 0.415 | 0.282 | Mo | 0.303 | 1 | 0 | 0.613 | 0.257 | Mo | 0.130 | 1 | 0 | 2.3 |
| 4 | 0.395 | 0.291 | Hf | 0.314 | 1 | 0 | 0.559 | 0.282 | Hf | 0.159 | 1 | 0 | 2.0 |
| 5 | 0.335 | 0.339 | Ta | 0.326 | 1 | 0 | 0.510 | 0.310 | Ta | 0.180 | 1 | 0 | 1.8 |
| 6 | 0.346 | 0.329 | W | 0.325 | 1 | 0 | 0.520 | 0.304 | W | 0.176 | 1 | 0 | 1.8 |
| 7 | 0.486 | 0.267 | Mo | 0.247 | 1 | 0 | 0.632 | 0.255 | Mo | 0.113 | 1 | 0 | 2.2 |
| 8 | 0.463 | 0.282 | Ta | 0.255 | 1 | 0 | 0.622 | 0.237 | Ta | 0.141 | 1 | 0 | 1.8 |
| 9 | 0.447 | 0.184 | Mo | 0.369 | 1 | 0 | 0.541 | 0.180 | Mo | 0.279 | 1 | 0 | 1.3 |
| 10 | 0.457 | 0.189 | Ta | 0.354 | 1 | 0 | 0.554 | 0.174 | Ta | 0.272 | 1 | 0 | 1.3 |
| 11 | 0.395 | 0.337 | Mo | 0.268 | 1 | 0 | 0.544 | 0.389 | Mo | 0.067 | 1 | 0 | 4.0 |
| 12 | 0.411 | 0.348 | Ta | 0.241 | 1 | 0 | 0.554 | 0.352 | Ta | 0.094 | 1 | 0 | 2.6 |
| 13 | 0.328 | 0.314 | Mo, W | 0.174, 0.184 | 1 | 0 | 0.614 | 0.275 | Mo, W | 0.060, 0.051 | 1 | 0 | 2.3 |
| 14 | 0.373 | 0.298 | Nb, Ta | 0.137, 0.192 | 1 | 0 | 0.567 | 0.301 | Nb, Ta | 0.554, 0.078 | 1 | 0 | 2.5 |
| 15 | 0.454 | 0.305 | Zr, Hf | 0.111, 0.130 | 1 | 0 | 0.599 | 0.286 | Zr, Hf | 0.063, 0.052 | 1 | 0 | 2.1 |
| 16 | 0.436 | 0.290 | Zr | 0.274 | 0.89 | 0.11 | 0.612 | 0.274 | Zr | 0.114 | 1 | 0 | 2.4 |
| 17 | 0.431 | 0.285 | Zr | 0.284 | 0.58 | 0.42 | 0.621 | 0.256 | Zr | 0.123 | 0.55 | 0.45 | 2.3 |
| 18 | 0.593 | 0.407 | — | 0 | 1 | 0 | 0.587 | 0.413 | — | 0 | 1 | 0 | — |
| 19 | 0.567 | 0.413 | — | 0 | 1 | 0 | 0.387 | 0.613 | — | 0 | 1 | 0 | — |
| 20 | 0.569 | 0.316 | Zr | 0.125 | 1 | 0 | 0.563 | 0.319 | Zr | 0.118 | 1 | 0 | 1.1 |
| 21 | 0.212 | 0.495 | Mb | 0.293 | 1 | 0 | 0.308 | 0.566 | Mo | 0.126 | 1 | 0 | 2.3 |
| 22 | 0.609 | 0.304 | V | 0.067 | 1 | 0 | 0.610 | 0.326 | V | 0.064 | 1 | 0 | 1.4 |
| 23 | 0.418 | 0.297 | Zr | 0.285 | 0.35 | 0.65 | 0.628 | 0.254 | Zr | 0.118 | 0.33 | 0.67 | 2.4 |
| 24 | — | — | — | — | — | — | — | — | — | — | — | — | — |
| 25 | 0.286 | 0.202 | Mo | 0.512 | 1 | 0 | 0.445 | 0.231 | Mo | 0.324 | 1 | 0 | 1.6 |
| 26 | 0.267 | 0.302 | Mo | 0.431 | 1 | 0 | 0.382 | 0.25 | Mo | 0.368 | 1 | 0 | 1.2 |

The TEM images were visually observed to evaluate continuous variation in chemical composition in the thickness direction. In the TEM images, a sample with continuous variation in lightness in the thickness direction was evaluated as having continuous variation in chemical composition (“present”), and a sample without continuous variation in lightness in the thickness direction was evaluated as not having continuous variation in chemical composition (“absent”).

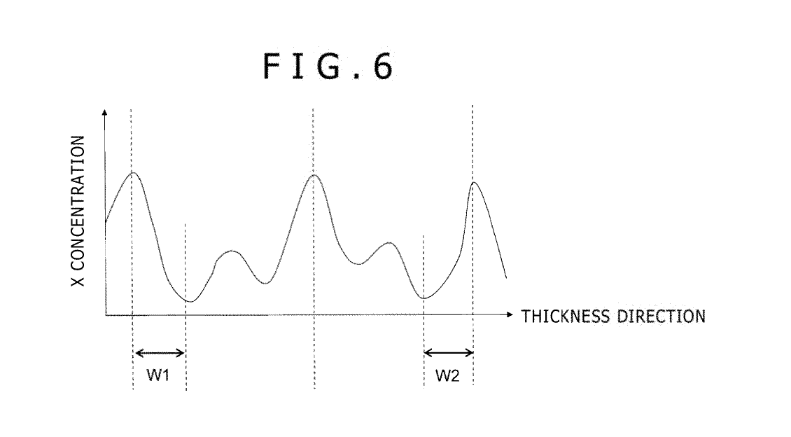

In Test Nos. 1 to 17, 19, 21, 23, 25, and 26, the distance between a minimum X concentration layer and a nearest maximum X continuation layer was determined at arbitrary five points, and the average of the measured distances was defined as the average distance between the maximum X concentration layer and the minimum X concentration layer. FIG. 6 schematically illustrates how to measure distances W1 and W2 between two minimum X concentration layers and corresponding nearest maximum X concentration layers, in a sample having a variation in chemical composition as with the variation in FIG. 2. The distance in the thickness direction between a maximum X concentration layer and a maximum X concentration layer adjacent to each other was measured at arbitrary five points, and the average of five measurements was defined as the average distance between the maximum X concentration layer and the maximum X concentration layer. Results of these are presented in Table 3.

Fibrous Microstructure Analysis

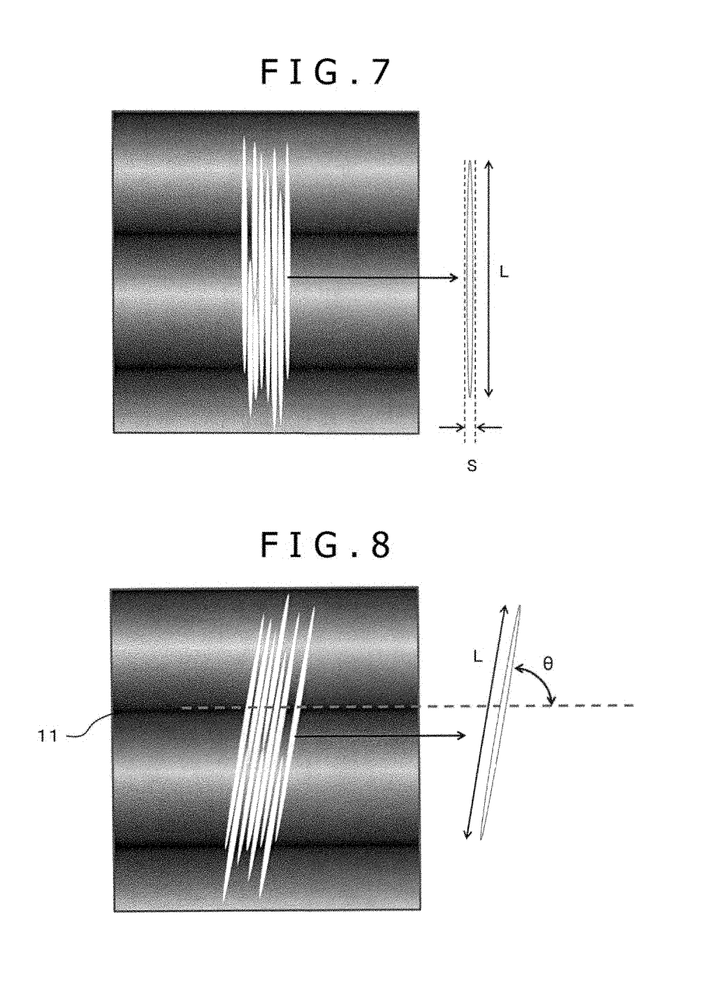

Using the images used in the “Chemical Composition Analyst”,the major axes and minor axes of crystal observed in the images were measured. FIG. 7 illustrates a schematic view of the crystals. As illustrated in FIG. 7, a rectangle circumscribing a crystal was assumed. Of the rectangle, the dimension L of the long side was defined as the major axis of the crystal; and the dimension S of the short side was defined as the minor axis of the crystal. In FIG. 7, only part of a fibrous microstructure is illustrated, for the sake of describing, in an easy-to-understand way, how the fibrous microstructure is in the hard coating according to the present invention. Since the crystals have different sizes (dimensions), ten crystals were measured, and the averages of ten measurements were defined as the average length of minor axes, and the average length of major axes. An average aspect ratio was determined on the basis of the average length of minor axes, and the average length of major axes. A microstructure including crystals having an average aspect ratio of 2.5 or more was determined as fibrous microstructure.

In addition, an angle which the major axis of crystals forms with a maximum X concentration layer was measured. FIG. 8 illustrates a schematic view of the crystals. As illustrated in FIG. 8, the angle θ was determined, where the angle θ was formed by the major axis L of the crystal with a layer defined by a series of the maximum X concentration points, namely, a maximum X concentration layer 11. In FIG. 8, only part of a fibrous microstructure is illustrated, for the sake of describing, in an easy-to-understand way, how the fibrous microstructure is in the hard coating according to the present invention. The angles with respect to three fibrous microstructure per one view field were measured, and the average of the three measurements was defined as the angle which the major axes of crystals form with the maximum X concentration layer. Results of these are presented in Table 3.

Next, cutting tests were performed in the following manner using the cutting test samples.

Cutting Tests

In this experimental example, wear resistance was evaluated by width of flank wear in the following manner. Specifically, the cutting test samples were subjected to cutting tests under conditions as follows, and the wear resistance was evaluated by the average wear width, which is the average of maximum widths of flank wear at the time point when 500 holes were cut.

Cutting Test Conditions
Work material: SCM 400 (hardness: 30 hardness on Rockwell C scale (HRC))
Work material thickness: 60 mm
Cutting speed: 75 m/min
Feed per tooth: 0.24 mm/REV
Hole depth: 23 mm from drill tip
Cutting fluid: YUSHIROKEN FGE 180 (diluting the stock fluid at a dilution powder of 15)
Cutting fluid supply: external supply

Wear Width Measurement

A sample cutting tool was placed so that a flank near to the tool edge and the objective lens were in parallel with each other, photographs of both edges were taken using an optical microscope at 200-fold magnification, and the average of maximum wear widths of the both edges was defined as the wear width. A sample with a deceasing wear width as determined above was evaluated as having more excellent wear resistance. Results of these are presented in Table 3. For Test Nos. 21 and 24, in which the cutting tool was broker before 500-hole-drilling, the numbers of drilled holes are described in Table 3.

TABLE 3

| | | | | | | | Average | | |
|---|---|---|---|---|---|---|---|---|---|
| | | | | | | | distance | | |
| | | Crystal | | | | | between | Average | |
| | | | | | | Angle which | maximum X | distance | |
| | | | | | | major axis | concentration | between | Cutting |
| | Continuous | Average | Average | | | forms with | layer and | adjacent | test |
| | variation in | minor | major | Average | | maximum X | minimum X | maximum X | Wear |
| Test | chemical | axis | axis | aspect | | concentration | concentration | concentration | width |
| number | composition | (nm) | (nm) | ratio | Shape | layer (°) | layer (nm) | layers (nm) | (μm) |
| 1 | present | 1.0 | 30.0 | 30.0 | fibrous | 88.0 | 22 | 45 | 31 |
| 2 | present | 0.8 | 21.0 | 26.3 | fibrous | 91.0 | 25 | 51 | 26 |
| 3 | present | 1.1 | 15.0 | 13.6 | fibrous | 83.0 | 15 | 34 | 24 |
| 4 | present | 4.0 | 16.0 | 4.0 | fibrous | 92.0 | 10 | 21 | 30 |
| 5 | present | 1.1 | 37.0 | 33.6 | fibrous | 89.0 | 30 | 67 | 29 |
| 6 | present | 2.0 | 10.0 | 5.0 | fibrous | 90.0 | 27 | 56 | 30 |
| 7 | present | 1.6 | 14.0 | 8.8 | fibrous | 82.0 | 35 | 71 | 28 |
| 8 | present | 0.7 | 16.0 | 22.9 | fibrous | 92.0 | 46 | 95 | 28 |
| 9 | present | 2.0 | 17.0 | 8.5 | fibrous | 80.0 | 35 | 81 | 32 |
| 10 | present | 3.2 | 22.0 | 6.9 | fibrous | 81.0 | 36 | 77 | 31 |
| 11 | present | 2.3 | 26.0 | 11.3 | fibrous | 89.0 | 32 | 65 | 21 |
| 12 | present | 1.4 | 18.0 | 12.9 | fibrous | 88.0 | 22 | 45 | 23 |
| 13 | present | 8.0 | 25.0 | 3.1 | fibrous | 94.0 | 17 | 34 | 26 |
| 14 | present | 1.3 | 30.0 | 23.1 | fibrous | 92.0 | 38 | 78 | 25 |
| 15 | present | 1.2 | 12.0 | 10.0 | fibrous | 90.0 | 27 | 59 | 29 |
| 16 | present | 4.0 | 21.0 | 5.3 | fibrous | 105.0 | 15 | 32 | 30 |
| 17 | present | 6.0 | 27.0 | 4.5 | fibrous | 79.0 | 22 | 48 | 36 |
| 18 | absent | 2.4 | 2.5 | 1.0 | granular | — | — | — | 130 |
| 19 | present | 1.0 | 1.2 | 1.2 | granular | — | 18 | 45 | 163 |
| 20 | absent | 2.2 | 1.9 | 0.9 | granular | — | — | — | 45 |
| 21 | present | 2.0 | 7.0 | 3.5 | fibrous | 106.0 | 15 | 32 | *266 |
| 22 | absent | 2.0 | 2.1 | 1.1 | granular | — | — | — | 116 |
| 23 | present | 5.0 | 12.0 | 2.4 | granular | 95.0 | 32 | 64 | 132 |
| 24 | — | — | — | — | — | — | — | — | **42 |
| 25 | present | 7 | 24 | 3.4 | fibrous | 109 | 31 | 75 | 54 |
| 26 | present | 3 | 8 | 27 | fibrous | 72 | 25 | 51 | 86 |

*broken at 266-hole drilling
**broken at 42-hole drilling

As shown in Table 3, Test Nos. 1 to 17 included hard coatings meeting the conditions specified in the present invention, and resulted in excellent wear resistance in terms of wear widths of 40 μm or less. In contrast, Test Nos. 18 to 26 in Table 3 failed to meet the conditions specified in the present invention and failed to have excellent wear resistance. Specifically, details of these test samples are described below.

Test No. 18 did not contain any element X, did not offer continuous variation in chemical composition as shown in FIG. 4B, and resulted in poor wear resistance in terms of a large wear width.

Test No. 19 offered continuous variation in chemical composition as shown in FIG. 4A, but did not contain any element X, had a low Al content and a large Cr content at minimum X concentration points, and resulted in poor wear resistance in terms of a large wear width.

Test No. 20 contained the element X, but did not offer continuous variation in chemical composition, as shown in FIG. 3B, and resulted in poor wear resistance in terms of a large wear width.

Test No. 21 offered continuous variation in chemical composition, but has a low Al content at maximum X concentration points, has a low Al content at minimum X concentration points, and resulted in poor wear resistance to cause the drill to be broken.

Test No. 22 did not contain any element X, but contained vanadium (V), which is an element other than the elements X, did not include a fibrous microstructure, and resulted in poor wear resistance in terms of a large wear width. Test No. 22 offered continuous variation in chemical composition, because the distance between the target and the substrate was varied periodically. However, this sample did not contain any element X, but contained vanadium (V), which is an element other than the elements X. Accordingly, no continuous variation in chemical composition was identified by visual observation.

Test No. 23 had a large carbon content to cause the coating to be brittle, and resulted in poor wear resistance in terms of a large wear width.

Test No. 24 did not include a hard coating, and resulted in poor wear resistance to cause the drill to be broken.

Test No. 25 contained the element X in a content larger than the upper limit at maximum X concentration points, suffered from brittleness of the coating, and resulted in poor wear resistance in terms of a large wear width.

Test No. 26 contained the element X in an excessively high content at minimum X concentrate points, suffered from brittleness of the coating, and resulted in poor wear resistance in terms of a large wear width.

While the present invention has been particularly described with reference to specific embodiments thereof, it is obvious to those skilled in the art that various changes and modifications may be made without departing from the spirit and scope of the present invention.

This application claims priority to Japanese Patent Application No. 2015-081410, filed on Apr. 13, 2015, the entire contents of which are incorporated herein by reference.

### INDUSTRIAL APPLICABILITY

The hard coating according to the present invention has excellent wear resistance and is useful in tools such as cutting tools and forming tools, in particular in tools for heavy cutting such as drilling and gear cutting.

### REFERENCE SIGNS LIST

11, 12 maximum X concentration layer
21, 22, 23 minimum X concentration layer
11A, 11B, 11C, 12A, 12B, 12C maximum X concentration point
22A, 22B, 22C minimum X concentration point

1. A hard coating to be disposed on or over a substrate surface, the hard coating comprising:
a nitride or a carbonitride each comprising:
Al;
Cr; and
at least one element X having an atomic number higher than Cr and selected from the group consisting of a Group 4 element; a Group 5 element; and a Group 6 element,
wherein
the hard coating has two or more maximum X concentration points present repeatedly in a vertical direction to the substrate surface, the maximum X concentrate points being points at which a concentration of the element X reaches maximal and having a compositional formula of AlₘCr₍₁₋ₘ₋ₙ₎Xₙ(N_{α}C_{(1-α)}), where m, n, and α are atomic ratios and satisfy: 0.25≦m≦0.70, 0.05≦n≦0.45, 1−m−n>0, and 0.50≦α≦1;
the hard coating has one or more minimum X concentration points present between adjacent two maximum X concentration points in the vertical direction, the minimum X concentration points being points at which the concentration of the element X reaches minimal and having a compositional formula of AlₓCr_{(1-x-y)}X_{y}(N_{β}C_{(1-β)}), where x, y, and β are atomic ratios and satisfy 0.40≦≦0.80, 0.01≦y≦0.35, 0.50≦β≦1, 1−x−y>0, and n/y>1.0; and
the hard coating has a chemical composition continuously varying in the vertical direction.

2. The hard coating according to claim 1, wherein the hard coating has a total thickness of 0.1 to 20 μm.

3. The hard coating according to claim 1, wherein
the hard coating comprises a fibrous microstructure, and
the fibrous microstructure comprises crystals having an average aspect ratio of 2.5 or more and having an angle of 60° to 120°, where the angle is formed by major axes of the crystals with a layer defined by a series of the maximum X concentration points.

4. The hard coating according to claim 3,
wherein the crystals have an average length of minor axes of 0.1 to 30 nm.

5. A hard-coated member, comprising:
a substrate; and
the hard coating according to claim 1 disposed on or over the substrate.

6. The hard coating according to claim 2, wherein
the hard coating comprises a fibrous microstructure, and
the fibrous microstructure comprises crystals having an average aspect ratio of 2.5 or more and having an angle of 60° to 120°, where the angle is formed by major axes of the crystals with a layer defined by a series of the maximum X concentration points.
